(19) United States
(12) Patent Application Publication
(10) Pub. No.: US 2006/0216893 A1
(43) Pub. Date: Sep. 28, 2006

(54) MANUFACTURING METHOD OF A FLASH MEMORY CELL

(76) Inventors: Leo Wang, Hsinchu (TW); Chien-Chih Du, Hsinchu (TW); Chao-Wei Kuo, Taipei City (TW); Cheng-Tung Huang, Kaohsiung (TW); Saysamone Pittikoun, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,806

(22) Filed: May 9, 2006

Related U.S. Application Data
(62) Division of application No. 10/908,577, filed on May 18, 2005.

(30) Foreign Application Priority Data
Jun. 21, 2004 (TW) 93117877

(51) Int. Cl. H01L 21/336; H01L 21/4763; H01L 21/44

(52) U.S. Cl. 438/264; 438/263; 438/649; 438/655

(57) ABSTRACT

A manufacturing method of a flash memory cell is provided. The flash memory cell includes a first conductive type substrate, a stacked gate structure, a first conductive type source/drain region, a metal silicide layer, an inter-layer dielectric layer and a contact plug. The first conductive type substrate has a second conductive type shallow well already formed thereon. The metal silicide layer is disposed within the first conductive type drain region. The contact plug is disposed within the inter-layer dielectric layer and electrically connected with the metal silicide layer in the first conductive type drain region to reduce resistance between the contact plug, the first conductive type drain region and the second conductive type shallow well and increase read-out speed of the flash memory.

### CROSS-REFERENCE TO RELATED APPLICATION

This is a divisional application of application Ser. No. 10/908,577, filed on May 18, 2005, which claims the priority benefit of Taiwan patent application serial no. 93117877, filed on Jun. 21, 2004 and is now pending. The entirety of each of the above-mentioned patent applications is hereby incorporated by reference herein and made a part of this specification.

### BACKGROUND OF THE INVENTION

1. Field of the Invention

The present invention relates to a manufacturing method of a memory device. More particularly, the present invention relates to a manufacturing method of a flash memory cell.

2. Description of the Related Art

Non-volatile memory is currently used inside many types of electronic devices for holding structural data, programming data and other randomly access transient data. One type of non-volatile memory that can be repeatedly access is called flash memory. In fact, flash memory is an electrically erasable programmable read only memory (EEPROM) device that allows multiple data writing, reading and erasing operations. In addition, the stored data will be retained even after power to the device is removed. With these advantages, it has been broadly applied in personal computer and electronic equipment.

FIG. 1 is a schematic cross-sectional view of a conventional flash memory cell (for example, the flash memory cell disclosed in U.S. Pat. No. 6,418,060). As shown in FIG. 1, the flash memory cell 70 includes at least a deep well 42, a shallow well 46, a stacked gate structure 40, a source region 48, a drain region 44, a conductive line (bit line) 72 and a contact plug 60a. The conductive line 72 is electrically connected to the drain region 44 and the shallow well 46 through the contact plug 60a. In other words, the contact plug 60a has to pass through the drain region 44 and the shallow well 46. To fabricate the contact plug 60a, an inter-layer dielectric layer (not labeled) and the deep well 42 have to be etched to form a contact opening that passes through the inter-layer dielectric layer, the drain region 44 and the shallow well 46. However, the contact plug opening has a large aspect ratio and at least two different types of materials have to be etched in the same operation. Hence, etching to a precise depth is rather difficult. Furthermore, the contact plug in the memory cell region and the contact plugs in the peripheral circuit regions must be separately formed in the later processing steps. This increases the complexity of the later processing step.

In addition, the contact plug 60a has a poor contact with the drain region 44 and the shallow well 46 (a small contact area for a vertical contact between the contact plug 60a and the drain region 44). Thus, the drain region 44 and the shallow well 46 may have a too large or too unstable resistance that the operating speed and efficiency of the memory cell is significantly affected when the memory cell is driven (especially, when reading data from the memory cell).

### SUMMARY OF THE INVENTION

Accordingly, at least one objective of the present invention is to provide a flash memory cell and manufacturing method thereof that can reduce resistance in the drain region and increase the data read-out speed of the memory cell.

At least a second objective of the present invention is to provide a flash memory cell having a faster data read-out speed.

To achieve these and other advantages and in accordance with the purpose of the invention, as embodied and broadly described herein, the invention provides a method of fabricating a flash memory cell. First, a second conductive type shallow well is formed over a first conductive type substrate. Thereafter, a gate stack layer is formed over the first conductive type substrate. The stacked gate structure includes a tunneling dielectric layer, a floating gate, an inter-gate dielectric layer and a control gate stacked sequentially over the first conductive type substrate. Furthermore, the stacked gate structure is disposed over the second conductive type shallow well. A first conductive type source region and a second conductive type drain region are formed in the first conductive type substrate within the second conductive type shallow well on each side of the gate structure. After that, a metal silicide layer is formed in the first conductive type drain region. The metal silicide layer passes through the first conductive type drain region and the junction with the second conductive type shallow well. An inter-layer dielectric layer is formed over the first conductive type substrate and the stacked gate structure. Finally, a contact plug is formed in the inter-layer dielectric layer such that the contact plug is electrically connected to the first conductive type drain region and the second conductive type shallow well through the metal silicide layer.

In the aforementioned method, after forming the inter-layer dielectric layer but before forming the contact plug, further includes performing an ion implantation using the inter-layer dielectric layer as a mask to form a doped region in the first conductive type drain region and the underlying second conductive type shallow well. The first conductive type drain region and the second conductive type shallow well are electrically shorted through the doped region, for example.

The present invention also provides an alternative method of fabricating a flash memory including the following steps. First, a second conductive type shallow well is formed over a first conductive type substrate. Thereafter, a stacked gate structure is formed over the first conductive type substrate. The stacked gate structure includes a tunneling dielectric layer, a floating gate, an inter-gate dielectric layer and a control gate stacked sequentially over the first conductive type substrate. The stacked gate structure is disposed over the second conductive type shallow well. After that, a first conductive type source region and a second conductive type drain region are formed in the first conductive type substrate within the second conductive type shallow well on each side of the gate structure. A metal silicide layer is formed in the first conductive type drain region and then a doped region is formed in the first conductive type drain region and its underlying second conductive type shallow well. The first conductive type drain region and the second conductive type shallow well are electrically shorted together through the doped region. Thereafter, an inter-layer dielectric layer is formed over the first conductive type substrate and the stacked gate structure. Finally, a contact plug is formed in the inter-layer dielectric layer to connect electrically with the metal silicide layer. Through the metal silicide layer, the contact plug is electrically connected to the first conductive type drain region and the second conductive type shallow well.

The present invention also provide yet another method of fabricating a flash memory including the following steps. First, a second conductive type shallow well is formed over a first conductive type substrate. Thereafter, a stacked gate structure is formed over the first conductive type substrate. The stacked gate structure includes a tunneling dielectric layer, a floating gate, an inter-gate dielectric layer and a control gate stacked sequentially over the first conductive type substrate. The stacked gate structure is disposed over the second conductive type shallow well. After that, a first conductive type source region and a second conductive type drain region are formed in the first conductive type substrate within the second conductive type shallow well on each side of the gate structure. A doped region is formed in the first conductive type drain region and its underlying second conductive type shallow region. The first conductive type drain and the second conductive type shallow well are electrically shorted together through the doped region. A metal silicide layer is formed in the first conductive type drain region and then an inter-layer dielectric layer is formed over the first conductive type substrate and the stacked gate structure. Finally, a contact plug is formed in the inter-layer dielectric layer to connect electrically with the metal silicide layer. Through the metal silicide layer, the contact plug is electrically connected to the first conductive type drain region and the second conductive type shallow well.

The method of fabricating the flash memory cell according to the present invention includes forming a metal silicide layer within the first conductive drain region and utilizing the metal silicide layer or another doped region underneath the metal silicide layer to form a short between the first conductive type drain region and the second conductive type shallow well. Through the metal silicide layer, the contact plug is electrically connected to the first conductive drain region and the second conductive type shallow well. Hence, the present invention obviates the need of using a complicated method to form a contact with a high aspect ratio.

The present invention also provides a flash memory cell including a first conductive type substrate, a stacked gate structure, a first conductive type source, a first conductive type drain, a metal suicide layer, an inter-layer dielectric layer and a contact plug. The first conductive type substrate has a second conductive shallow well already formed therein. The stacked gate structure is disposed over the first conductive type substrate. The stacked gate structure includes a tunneling dielectric layer, a floating gate, an inter-gate dielectric layer and a control gate sequentially stacked over the first conductive type substrate. The first conductive type source and the first conductive drain are disposed in the first conductive type substrate within the second conductive type shallow well on each side of the stacked gate structure. The metal silicide layer is disposed in the first conductive type drain region and the inter-layer dielectric layer is disposed over the first conductive type substrate and the stacked gate structure. The contact plug is disposed in the inter-layer dielectric layer. Through the metal silicide layer, the contact plug connects electrically with the first conductive type drain and the second conductive type shallow well.

In the flash memory cell of the present invention, the first conductive type drain region and the second conductive type shallow well are electrically shorted together through the metal silicide layer or the doped region and the contact lug is electrically connected to the metal silicide layer. Because the metal silicide layer is capable of lowering the resistance between the contact plug, the first conductive type drain region and the second conductive type shallow well, data read-out rate from the memory cell is increased. Ultimately, the performance of the memory cell is improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional flash memory cell.

FIGS. 2A through 2E are schematic cross-sectional views showing the steps for fabricating a flash memory cell according to one embodiment of the present invention.

FIGS. 3A and 3B are schematic cross-sectional views showing some of the steps for fabricating a flash memory cell according to another embodiment of the present invention.

FIGS. 4A and 4B are schematic cross-sectional views showing some of the steps for fabricating a flash memory cell according to yet another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The flash memory cell in the present invention has a higher data read-out rate and a more consistent performance. Furthermore, the flash memory cell can be fabricated using a variety of processes. In the following, a few embodiments are described to illustrate these different types of fabrication using a binary NOR (BiNOR) gate flash memory array as an example. However, the following embodiments serve to illustrate rather than limit the scope of the present invention. Anyone familiar with the semiconductor fabrication technique may make some modifications within the spirit of the present invention. It should be noted that the first conductive type is an n-type and the second conductive type is a p-type in the following embodiments. Yet, the present invention is equally valid if the first conductive type is a p-type and the second conductive type is an N-type.

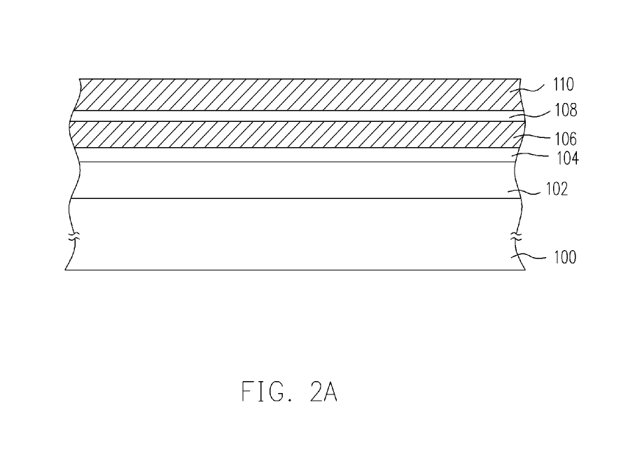

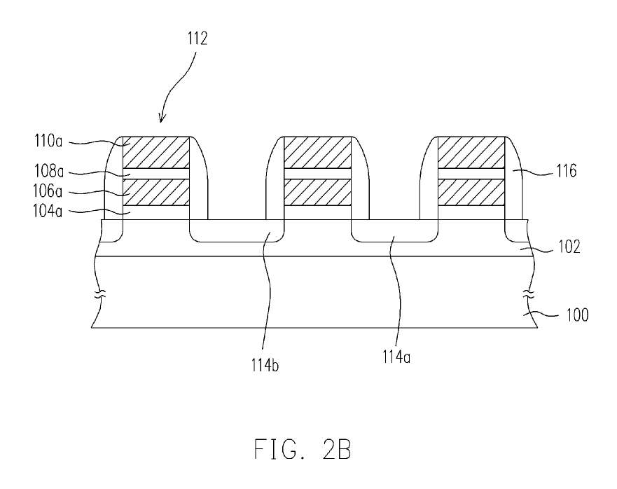

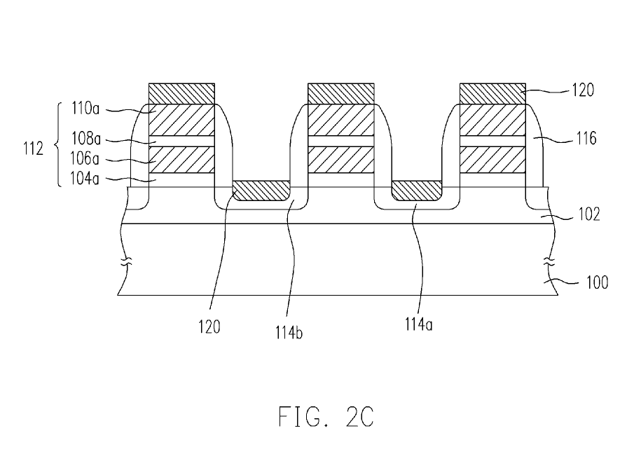

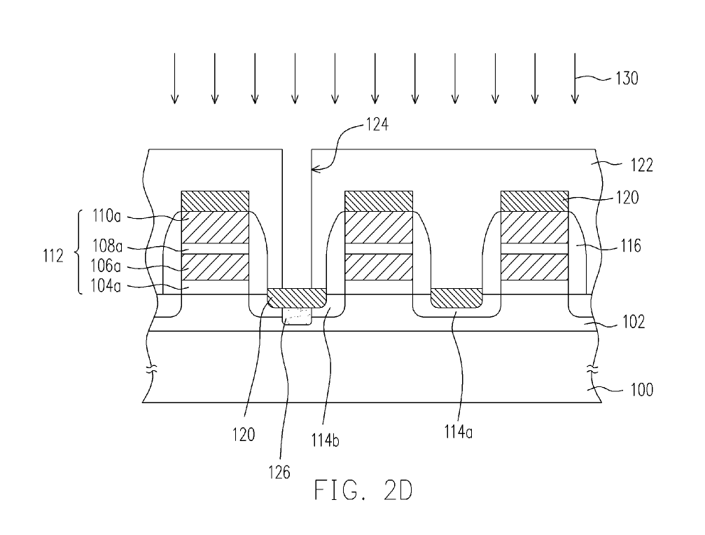

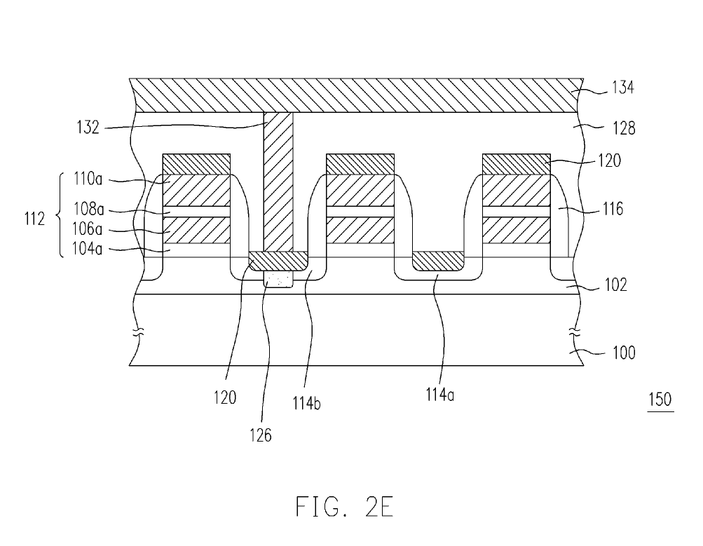

FIGS. 2A through 2E are schematic cross-sectional views showing the steps for fabricating a flash memory cell according to one embodiment of the present invention. As shown in FIG. 2A, a p-type shallow well 102 is formed in an n-type substrate 100. Thereafter, a tunneling dielectric layer 104, a conductive layer 106, a dielectric layer 108 and another conductive layer 110 are sequentially formed over the n-type substrate 100. The dielectric layer 104 is a silicon oxide layer formed, for example, by performing a thermal oxidation. The dielectric layer 108 is an oxide/nitride/oxide composite layer, an oxide/nitride composite layer or a silicon oxide layer formed, for example, by carrying out a low-pressure chemical vapor deposition (LPCVD). The conductive layer 106 and the conductive layer 110 are doped polysilicon layers formed, for example, by carrying out a chemical vapor deposition to form an undoped polysilicon layer and implanting ions into the undoped polysilicon layer. Obviously, the conductive layer 106 and the conductive layer 110 can be fabricated in an in-situ ion doping and chemical vapor deposition process.

In addition, a cap layer (not shown) is also permitted to form over the conductive layer 110 to protect the conductive layer 110 against possible damages resulting from subsequent processes (for example, an etching process).

As shown in FIG. 2B, the dielectric layer 104, the conductive layer 106, the dielectric layer 108 and the conductive layer 110 are patterned to form a plurality of stacked gate structures 112 on the n-type substrate 100 by performing a photolithographic/etching process, for example. Each stacked gate structure 112 includes a tunneling dielectric layer 104a, a floating gate 106a, an inter-gate dielectric layer 108a and a control gate 110a sequentially stacked over the n-type substrate 100. Thereafter, an n-type source region 114a and an n-type drain region 114b are formed in the n-type substrate 100 within the p-type shallow well 102 on each side of the stacked gate structure 112. The n-type source region 114a and the n-type drain region 114b are formed, for example, by implanting n-type dopants into the p-type shallow well 102. In one preferred embodiment, spacers 116 are formed on the sidewalls of the stacked gate structures 112. The spacers 116 are fabricated using an insulating material, for example. The spacers 116 are formed, for example, by depositing insulating material to form a conformal insulating layer (not shown) over the n-type substrate 100 and performing an anisotropic etching to remove a portion of the conformal insulating layer. In another embodiment of the present invention, the distance separating neighboring stacked gate structures 112 can be brought closer to each other (that is, width of the n-type source region 114a reduced). Hence, the spacers 116 on the n-type source region 114a beside the stacked gate structures 112 are joined up to cover the entire n-type source region 114a.

As shown in FIG. 2C, a metal silicide layer 120 is formed over the n-type drain region 114b. The metal silicide layer 120 is a nickel silicide, tungsten silicide, a cobalt silicide, a titanium silicide, a platinum silicide or a palladium silicide layer, for example. The metal silicide layer 120 is formed, for example, by performing a self-aligned metal silicide process. First, a metallic layer (for example, a nickel, tungsten, cobalt, titanium, platinum or palladium layer) (not shown) is formed over the n-type substrate 100 and the stacked gate structures 112 in a physical vapor deposition (PVD) process. Thereafter, a thermal processing is carried out so that the metallic atoms within the metallic layer react with the silicon atoms within the n-type substrate 100 to form the metal silicide layer. Finally, any unreacted or partially reacted metal is removed. In one preferred embodiment, the control gate 110a of the stacked gate structure 112 and the silicon within the n-type source region 114a also react with the metallic layer to form a metal silicide layer. Consequently, a metal silicide layer 120 is also formed over the control gate 110a and within the n-type source region 114a.

Obviously, if the distance separating two neighboring stacked gate structures 112 that uses a common n-type source region 114a is small (that is, the width of the n-type source region 114a is small) so that the spacers 116 on the n-type source region 114a beside the stacked gate structures 112 cover the n-type source region 114a entirely, no metal silicide layer is formed on the n-type source region 114a after the aforementioned self-aligned metal silicide process. Although the aforementioned self-aligned metal silicide process is carried out within the memory cell region, the self-aligned metal silicide process is actually integrated with other complimentary metal-oxide-semiconductor (CMOS) process for forming the peripheral circuit.

As shown in FIG. 2D, a photoresist layer 122 having an opening 124 therein is formed over the n-type substrate 100 and the stacked gate structures 112. The patterned photoresist layer 122 is formed, for example, by performing a photolithographic/etching process. Using the photoresist layer 122 as a mask, ions 130 are implanted into the n-type drain region 114b and the p-type shallow well 102 underneath the metal silicide layer 120 through the opening 124 to form a doped region 126. The doped region 126 passes through the n-type drain region 114b and the junction with the p-type shallow well 102. The ions 130 used for forming the doped region 126 in the ion implantation include boron difluoride (BF₂) ions, for example.

As shown in FIG. 2E, the photoresist layer 122 is removed. Thereafter, an inter-layer dielectric layer 128 is formed over the n-type substrate 100 and the stacked gate structures 112. The inter-layer dielectric layer 128 is fabricated using borophosphosilicate glass (BPSG) or phosphosilicate glass (PSG) in a chemical vapor deposition, for example. The inter-layer dielectric layer 128 is planarized, for example, by back etching or performing a chemical-mechanical polishing process. After that, a contact plug 132 is formed in the inter-layer dielectric layer 128 such that the contact plug 132 is electrically connected to the metal silicide layer 120. The contact plug 132 is a tungsten plug formed, for example, by forming an opening (not shown) in the inter-layer dielectric layer 128 that exposes the metal silicide layer 120 within the n-type drain region 114b and then depositing conductive material to fill the opening.

Thereafter, a conductive line 134 having an electrical connection with the contact plug 132 is formed over the inter-layer dielectric layer 128 to produce a complete flash memory cell 150. To form the linear conductive line 134, conductive material is deposited over the inter-layer dielectric layer 128 to form a conductive layer (not shown) and then a photolithographic and etching process is carried out pattern the conductive layer. Thereafter, conventional processes are used to produce a complete flash memory. Since the remaining steps should be familiar to those skilled in the art of semiconductor fabrication, a detailed description is omitted.

In the present invention, a metal silicide layer 120 is formed within the n-type drain region 114b and a doped region 126 that passes through the n-type drain 114b and the junction with the p-type shallow well 102 is formed underneath the metal silicide layer 120. Hence, a short circuit is formed between the n-type drain region 114b and the p-type shallow well 102. Thereafter, a contact plug 132 having electrical connection with the metal silicide layer is formed. This obviates the need for deploying a difficult and complicated method to form a contact opening with a high aspect ratio.

In another embodiment of the present invention, the inter-layer dielectric layer 128 (as shown in FIG. 2E) is formed before performing the ion implantation in FIG. 2D. Thereafter, using the inter-layer dielectric layer 128 as a mask, the ion implantation for forming the doped region (as shown in FIG. 2D) is carried out. Finally, conductive material is deposited into the opening 124 shown in FIG. 2D to form the contact plug 132 (as shown in FIG. 2E). In other words, there is no need to fabricate a photoresist layer because the inter-layer dielectric layer 128 can be directly used as an implant mask in the process of forming the doped region 126. Thus, one less masking step is required and some production cost can be reduced.

In the following, the flash memory cell fabricated according to the aforementioned method of the present invention is described. As shown in FIG. 2E, the flash memory cell 150 mainly includes an n-type substrate 100, a stacked gate structure 112, an n-type source region 114a, an n-type drain region 114b, a metal silicide layer 120, an inter-layer dielectric layer 128 and a conductive line 134. The n-type substrate 100 has a p-type shallow well 102 already formed thereon. The stacked gate structure 112 is disposed on the n-type substrate 100. The stacked gate structure 112 includes a tunneling dielectric layer 104a, a floating gate 106a, an inter-gate dielectric layer 108a and a control gate 110a sequentially stacked over the n-type substrate 100. The n-type source region 114a and the n-type drain region 114b are disposed in the n-type substrate 100 within the p-type shallow well 102 on each side of the stacked gate structure 112. The metal silicide layer 120 is disposed within the n-type drain region 114b and the inter-layer dielectric layer 128 is disposed over the n-type substrate 100 and the stacked gate structure 112. The contact plug 132 is formed in the inter-layer dielectric layer 128 and is electrically connected to the metal silicide layer 120 within the n-type drain region 114b. In addition, the conductive line 134 is disposed over the inter-layer dielectric layer 128. The conductive line 134 is electrically connected to the n-type drain region 114b through the contact plug 132 to serve as a bit line for the flash memory cell 150.

In addition, the flash memory cell 150 further includes a doped region 126 formed within the n-type drain region 114b and its underlying p-type shallow well 102 so that the n-type drain region 114b and the p-type shallow well 102 are electrically shorted together through the doped region 126. Furthermore, a metal silicide layer 120 is also formed over the stacked gate structure 112 to lower the resistance at the control gate 110a.

With the metal silicide layer 120 disposed within the n-type drain region 114b of the flash memory cell 150, the average resistance at the n-type drain region 114b is reduced. Since the contact plug 132 is electrically connected to the n-type drain region 114b and the p-type shallow well 102 through the metal silicide layer 120, the resistance between the contact plug 132, the n-type drain region 114b and the p-type shallow well 102 is also reduced. Ultimately, the speed for reading data from the flash memory cell 150 is increased so that overall performance of the memory device is improved.

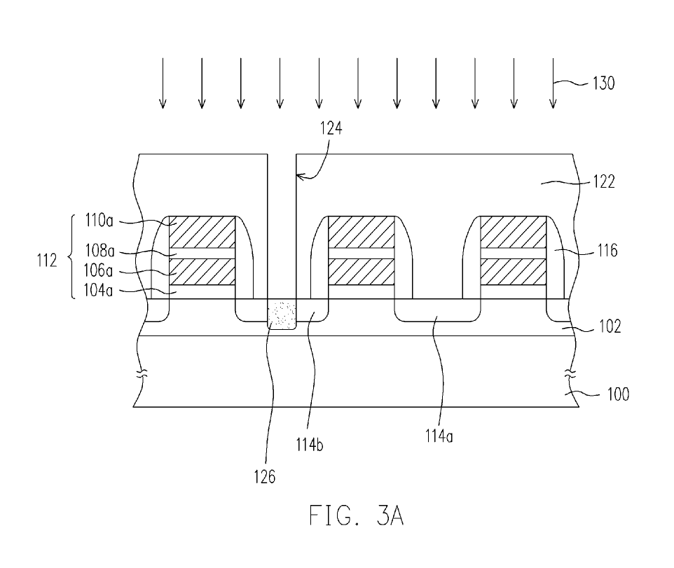

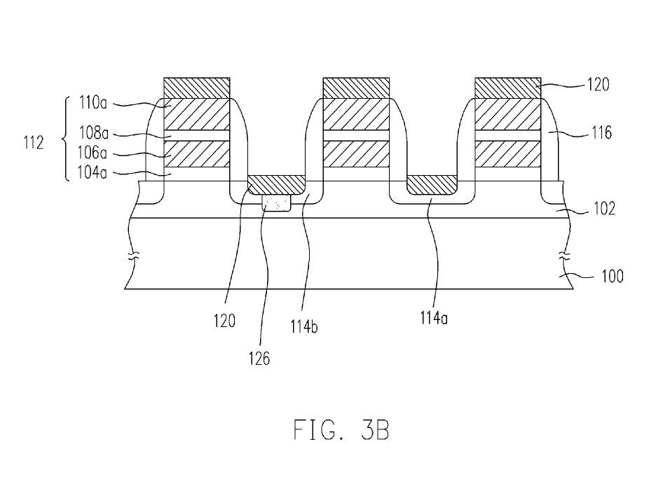

The present invention also permits forming a doped region within the n-type drain region and p-type shallow well before forming a metal silicide layer within the n-type drain region so that the energy level demanded to form the doped region is reduced. FIGS. 3A and 3B are schematic cross-sectional views showing some of the steps for fabricating a flash memory cell according to another embodiment of the present invention. In the present embodiment, components identical to the first embodiment are labeled identically so that detailed description of its method of fabrication and the material are not repeated.

As shown in FIG. 3A, after forming the structure as shown in FIG. 2B, a photoresist layer 122 having an opening 124 therein is formed over the n-type substrate 100 and the stacked gate structure 112. Thereafter, using the photoresist layer 122 as a mask, an ion implantation is carried out implanting ions 130 through the opening 124 into the n-type drain region 114b and the p-type shallow well 102 underneath the metal silicide layer 120 to form a doped region 126.

As shown in FIG. 3B, the photoresist layer 122 is removed. Thereafter, a metal suicide layer 120 is formed within the n-type drain region 114b. In one embodiment of the present invention, this same step can produce a metal silicide layer 120 within the n-type source region 114a as well as the top of the stacked gate structure 112. After that, the steps in FIG. 2E according to the first embodiment are carried out to form the flash memory cell 150 as shown in FIG. 2E.

In addition, the present invention also permits the metal silicide layer to be directly used as a conductive medium for electrically connecting the n-type drain region 114b and the p-type shallow well 102 together. This is explained in more detailed in the following.

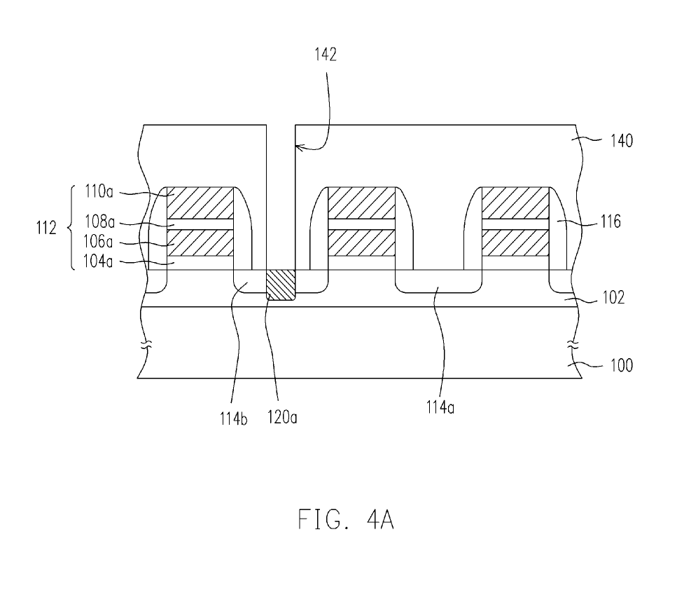

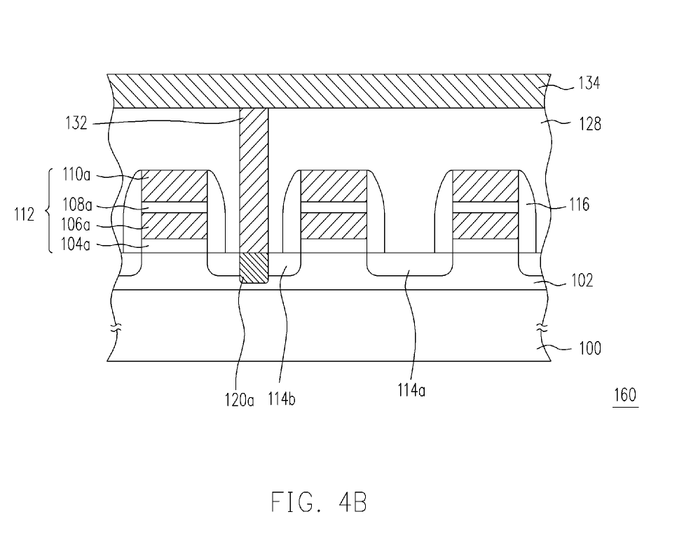

FIGS. 4A and 4B are schematic cross-sectional views showing some of the steps for fabricating a flash memory cell according to yet another embodiment of the present invention. As shown in FIG. 4A, after forming the structure as shown in FIG. 2B, a mask layer 140 having an opening 142 therein is formed over the n-type substrate 100. The opening 142 exposes a portion of the n-type drain region 114b. Thereafter, using the mask layer 140 as a mask layer, a metal silicide layer 120a is formed within the n-type drain region 114b. The metal silicide layer 120a passes through the n-type drain region 114b and the junction with the p-type shallow well 102 so that the n-type drain region 114b and the p-type shallow well 102 are electrically shorted together through the metal silicide layer 120a.

To form the metal silicide layer 120a, an etching operation is carried out using the mask layer 140 as a hard mask to form an opening (not shown) in the n-type substrate 100 that passes through the junction between the n-type drain region 114b and the p-type shallow well 102. Thereafter, metallic material is deposited into the opening and then a thermal treatment is carried out so that the metallic material reacts with silicon in the n-type drain region 114b and the p-type shallow well 102 to form the metal silicide layer 120a. In addition, the metal suicide layer 120a can be fabricated by performing an ion implantation using the mask layer 140 as a mask. In the ion implantation, metallic ions are implanted into the n-type substrate 100 so that the metallic ions react with silicon in the n-type drain region 114b and the p-type shallow well 102 to form the metal silicide layer 120a. However, the method of fabricating the metal silicide layer 120a is not limited to the aforementioned processes. In general, anyone familiar with the technique may select a method of fabricating the metal silicide layer 120a determined by the actual processing requirements according to the spirit of the present invention.

As shown in FIG. 4B, the mask layer 140 is removed and then the process shown in FIG. 2E of the first embodiment is carried out to form a flash memory cell 160.

If the distance separating neighboring stacked gate structures 112 that uses the same n-type source region 114a is small (that is, width of the n-type source region 114a is small), the spacers 116 beside the stacked gate structures 112 may join up to cover the entire n-type source region 114a. Furthermore, most memory device has a cap layer (not shown) formed over the control gate 110a to protect the control gate 110a. Hence, the spacers 116 can be directly used as a mask in a self-aligned metal silicide process instead of fabricating the mask layer 140. In other words, there is no need to form the mask layer 140 and then removing it thereafter.

In the present invention, a metal silicide layer 120a is formed within the n-type drain region 114b to pass through the junction between the n-type drain region 114b and the p-type shallow well 102 so that the n-type drain 114b and the p-type shallow well 102 are electrically shorted together. Thereafter, a contact plug 132 having electrical connection with the metal silicide layer 120a is formed so that the contact plug 132 is electrically connected to the n-type drain region 114b and the p-type shallow well 102 through the metal suicide layer 120a. This obviates the need for deploying a difficult and complicated method to form a contact opening with a high aspect ratio.

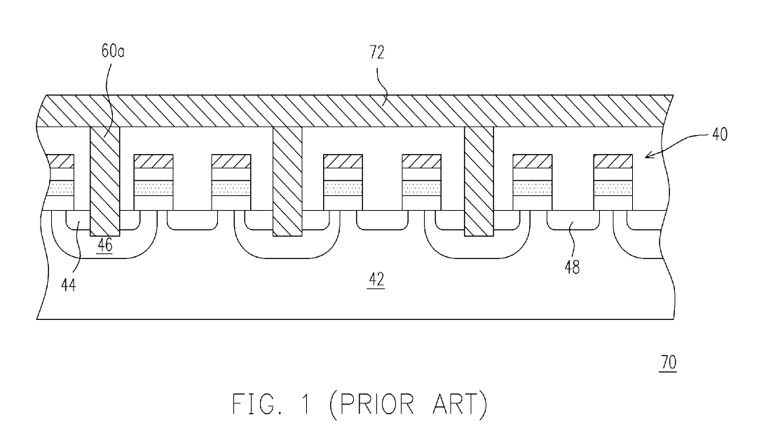

One major difference between the flash memory cell 160 fabricated in the aforementioned process and the flash memory cell 150 in FIG. 2E is the electrical conductive medium connecting the n-type drain region 114b and the p-type shallow well 102. The n-type drain region 114b and the p-type shallow well 102 in the flash memory cell 150 are electrically shorted together through the doped region 126 (shown in FIG. 2E). On the other hand, the n-type drain region 114b and the p-type shallow well 102 in the flash memory cell 160 are electrically shorted together through the metal silicide layer 120a (shown in FIG. 4B). Since other components in these two embodiments are identical or similar to the ones in FIG. 1E, detailed description of them is omitted.

In summary, major advantages of the present invention includes:

1. The n-type drain region and the p-type shallow well are electrically shorted together through a metal silicide layer or an additional doped region underneath the metal silicide layer. Thereafter, a contact plug is electrically connected to the metal silicide layer to eliminate the process of forming a contact plug that penetrates through the junction between the n-type drain region and the p-type shallow well. This obviates the need to form a contact plug opening with a large aspect ratio by performing difficult and complicated steps. Thus, the degree of complexity of the fabricating process is lowered. Furthermore, the contact plug within the memory cell region and the peripheral circuit region can be formed together in a subsequent stage, subsequent stage processing is simplified.

2. Since a metal silicide layer is formed in the n-type drain region, average resistance of the n-type drain region is lowered and the memory device has a more uniform resistance.

3. Since the contact plug is electrically connected to the n-type drain region and the p-type shallow well through a metal silicide layer, the average resistance between the contact plug, the n-type drain region and the p-type shallow well is reduced. Therefore, the memory cell can have a higher read-out rate and a better performance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a flash memory cell, comprising:
providing a first conductive type substrate;
forming a second conductive type shallow well in the first conductive type substrate;
forming a stacked gate structure over the first conductive type substrate, wherein the stacked gate structure comprises a tunneling dielectric layer, a floating gate, an inter-gate dielectric layer and a control gate sequentially stacked over the first conductive type substrate and the stacked gate structure is disposed over the second conductive type shallow well;
forming a first conductive type source region and a first conductive type drain region in the first conductive type substrate within the second conductive type shallow well on each side of the stacked gate structure;
forming a metal silicide layer within the first conductive type drain region such that the metal silicide layer passes through the junction between the first conductive type drain region and the second conductive type shallow well;
forming an inter-layer dielectric layer over the first conductive type substrate and the stacked gate structure; and
forming a contact plug in the inter-layer dielectric layer such that the contact plug is electrically connected to the first conductive type drain region and the second conductive type shallow well through the metal silicide layer.

2. The method of claim 1, wherein after forming the first conductive type source region and the first conductive type drain region but before forming the inter-layer dielectric layer, further comprises forming spacers on the sidewalls of the stacked gate structure.

3. The method of claim 1, wherein the step of forming the metal silicide layer within the first conductive type drain region further comprises forming the metal silicide layer over the control gate of the stacked gate structure.

4. The method of claim 1, wherein the first conductive type is n-type and the second conductive type is p-type.

5. A method of fabricating a flash memory cell, comprising:
providing a first conductive type substrate;
forming a second conductive type shallow well in the first conductive type substrate;
forming a stacked gate structure over the first conductive type substrate, wherein the stacked gate structure comprises a tunneling dielectric layer, a floating gate, an inter-gate dielectric layer and a control gate sequentially stacked over the first conductive type substrate and the stacked gate structure is disposed over the second conductive type shallow well;
forming a first conductive type source region and a first conductive type drain region in the first conductive type substrate within the second conductive type shallow well on each side of the stacked gate structure;
forming a metal silicide layer within the first conductive type drain region;
forming a doped region underneath the metal silicide layer such that the doped region connects electrically with the metal silicide layer and passes through the junction between the first conductive type drain region and the second conductive type shallow well;
forming an inter-layer dielectric layer over the first conductive type substrate and the stacked gate structure, wherein the inter-layer dielectric layer has an opening that exposes a portion of the first conductive type drain region; and
forming a contact plug inside the opening of the inter-layer dielectric layer such that the contact plug is electrically connected to the first conductive type drain and the second conductive type shallow well through the metal silicide layer and the doped region.

6. The method of claim 5, wherein after forming the metal silicide layer but before forming the inter-layer dielectric layer, further comprises:
forming a patterned photoresist layer over the stacked gate structure and the first conductive type substrate to expose the metal silicide layer;
forming the doped region using the patterned photoresist layer as a mask; and
removing the patterned photoresist layer.

7. The method of claim 5, wherein the step of forming the doped region comprises performing an ion implantation.

8. The method of claim 5, wherein the step of forming the metal silicide layer within the first conductive type drain region further comprises forming the metal silicide layer over the control gate of the stacked gate structure.

9. The method of claim 5, wherein the first conductive type is n-type and the second conductive type is p-type.

10. A method of fabricating a flash memory cell, comprising:
providing a first conductive type substrate;
forming a second conductive type shallow well in the first conductive type substrate;
forming a stacked gate structure over the first conductive type substrate, wherein the stacked gate structure comprises a tunneling dielectric layer, a floating gate, an inter-gate dielectric layer and a control gate sequentially stacked over the first conductive type substrate and the stacked gate structure is disposed over the second conductive type shallow well;
forming a first conductive type source region and a first conductive type drain region in the first conductive type substrate within the second conductive type shallow well on each side of the stacked gate structure;
forming a doped region within the first conductive type drain region such that the doped region passes through the junction between the first conductive type drain region and the second conductive type shallow well;
forming a metal silicide layer within the first conductive type drain region such that the metal silicide layer is electrically connected to the doped region;
forming an inter-layer dielectric layer over the first conductive type substrate and the stacked gate structure, wherein the inter-layer dielectric layer has an opening that exposes a portion of the first conductive type drain region; and
forming a contact plug inside the opening of the inter-layer dielectric layer such that the contact plug is electrically connected to the metal silicide layer.

11. The method of claim 10, wherein after forming the first conductive type source region and the first conductive type drain region but before forming the metal silicide layer, further comprises forming spacers on the sidewalls of the stacked gate structure such that the metal silicide layer is disposed over the exposed portion of the first conductive type drain region between the spacers.

12. The method of claim 10, wherein the step of forming the metal silicide layer within the first conductive type drain region further comprises forming the metal silicide layer over the control gate of the stacked gate structure.

13. The method of claim 10, wherein the step of forming the doped region comprises:
forming a patterned photoresist layer over the first conductive type substrate and the stacked gate structure to expose a portion of the first conductive type drain region;
forming the doped region in the first conductive type drain region and its underlying second conductive type shallow well exposed by the patterned photoresist layer; and
removing the patterned photoresist layer.

14. The method of claim 10, wherein the step of forming the doped region comprises performing an ion implantation.

15. The method of claim 10, wherein the first conductive type is n-type and the second conductive type is p-type.
